(19) United States
(12) Patent Application Publication
(10) Pub. No.: US 2013/0133729 A1
(43) Pub. Date: May 30, 2013

(54) SOLAR CELL AND MANUFACTURING METHOD THEREOF

(71) Applicants: Chan-Bin MO, Yongin-si (KR); Doo-Youl LEE, Yongin-si (KR); Young-Jin KIM, Yongin-si (KR); Min-Seok OH, Yongin-si (KR); Yun-Seok LEE, Yongin-si (KR); Nam-Kyu SONG, Yongin-si (KR); Cho-Young LEE, Yongin-si (KR); Young-Su KIM, Yongin-si (KR); Young-Sang PARK, Yongin-si (KR)

(72) Inventors: Chan-Bin MO, Yongin-si (KR); Doo-Youl LEE, Yongin-si (KR); Young-Jin KIM, Yongin-si (KR); Min-Seok OH, Yongin-si (KR); Yun-Seok LEE, Yongin-si (KR); Nam-Kyu SONG, Yongin-si (KR); Cho-Young LEE, Yongin-si (KR); Young-Su KIM, Yongin-si (KR); Young-Sang PARK, Yongin-si (KR)

(21) Appl. No.: 13/562,751

(22) Filed: Jul. 31, 2012

(30) Foreign Application Priority Data
Nov. 25, 2011 (KR) 10-2011-0124527

(51) Int. Cl. H01L 31/0224; H01L 31/18

(52) U.S. Cl. 136/255; 438/87; 257/E31.126

(57) ABSTRACT

A solar cell includes a semiconductor substrate, a first intrinsic semiconductor layer and a second intrinsic semiconductor layer on the semiconductor substrate, the first intrinsic semiconductor layer and the second intrinsic semiconductor layer being spaced apart from each other, a first conductive semiconductor layer and a second conductive semiconductor layer respectively disposed on the first intrinsic semiconductor layer and the second intrinsic semiconductor layer, and a first electrode and a second electrode, each including a bottom layer on the first conductive semiconductor layer and the second conductive semiconductor layer, respectively, the bottom layer including a transparent conductive oxide, and an intermediate layer on the bottom layer, the intermediate layer being including copper.

### BACKGROUND

1. Field

The described technology relates generally to a solar cell and a manufacturing method. Particularly, the described technology relates generally to a back surface electrode type of solar cell and a manufacturing method thereof.

2. Description of the Related Art

Regarding a solar cell, when an electrode electrically connected to an emitter and a substrate is positioned on a sunlight incidence plane of the solar cell, the electrode is also positioned on the emitter so that a light incidence area may be limited and the efficiency of the solar cell may be reduced.

Therefore, in order to increase the light incidence area, a back contact solar cell has been developed in which electrodes for collecting electrons and holes are positioned on a back surface.

An electrode that is formed by a screen printing method or an electrode that is formed by a plating process is usable for the electrode of the back surface electrode solar cell. The resistance of the plated electrode is very low, making it suitable for a high-efficiency solar cell.

The above information disclosed in this Background section is only for enhancement of understanding of the background of the described technology and therefore it may contain information that does not form the prior art that is already known in this country to a person of ordinary skill in the art.

### SUMMARY

According to an embodiment, there is provided a solar cell including a semiconductor substrate, a first intrinsic semiconductor layer and a second intrinsic semiconductor layer on the semiconductor substrate, the first intrinsic semiconductor layer and the second intrinsic semiconductor layer being spaced apart from each other, a first conductive semiconductor layer and a second conductive semiconductor layer respectively disposed on the first intrinsic semiconductor layer and the second intrinsic semiconductor layer, and a first electrode and a second electrode, including a bottom layer on the first conductive semiconductor layer and the second conductive semiconductor layer, respectively, the bottom layer including a transparent conductive oxide, and an intermediate layer on the bottom layer, the intermediate layer including copper.

The intermediate layer may include a part that is narrower than the bottom layer. The intermediate layer may include a part having a width that is equivalent to a width of the bottom layer.

The solar cell may further include a top layer on the intermediate layer, the top layer including tin. The top layer may cover the intermediate layer.

The transparent conductive oxide may include at least one of fluorine-doped tin oxide, indium tin oxide (ITO) indium oxide (In₂O₃), indium tungsten oxide (IWO), indium titanium oxide (ITiO), indium molybdenum oxide (IMO), indium niobium oxide (INbO), indium gadolinium oxide (IGdO), indium zinc oxide (IZO), indium zirconium oxide (IZrO), aluminum-doped zinc oxide (AZO), zinc oxide (ZnO), boron-doped zinc oxide (BZO), and gallium-doped zinc oxide (GZO).

The first conductive semiconductor layer may be doped with a p-type conductive impurity. The second conductive semiconductor layer may be doped with an n-type conductive impurity.

The semiconductor substrate may be in a form of a crystalline semiconductor. The first conductive semiconductor layer, the second conductive semiconductor layer, the first intrinsic semiconductor layer, and the second intrinsic semiconductor layer may include amorphous silicon.

According to an embodiment, there is provided a method for manufacturing a solar cell, the method including forming a first intrinsic semiconductor layer and a second intrinsic semiconductor layer on a semiconductor substrate, forming a first conductive semiconductor layer and a second conductive semiconductor layer on the first intrinsic semiconductor layer and the second intrinsic semiconductor layer, respectively, forming a bottom layer including a transparent conductive oxide on the first conductive semiconductor layer and the second conductive semiconductor layer, forming a resist pattern on the semiconductor substrate, the resist pattern including an opening exposing the bottom layer to provide an exposed bottom layer, forming an intermediate layer by plating copper on the exposed bottom layer, and removing the resist pattern.

The method may further include forming a top layer with tin on the intermediate layer.

The forming of the bottom layer may include removing the bottom layer between the first conductive semiconductor layer and the second conductive semiconductor layer.

In the forming of the bottom layer, the bottom layer may be formed on an entirety of the semiconductor substrate. After the removing of the resist pattern, the bottom layer between the first conductive semiconductor layer and the second conductive semiconductor layer may be removed using the intermediate layer as a mask.

The forming of the bottom layer may include forming a first bottom layer on the first conductive semiconductor layer and forming a second bottom layer on the second conductive semiconductor layer, the first bottom layer and the second bottom layer each including the transparent conductive oxide. The forming of the resist pattern may include forming the resist pattern to include openings exposing the first bottom layer on the first conductive semiconductor layer and the second bottom layer on the second conductive semiconductor layer to provide an exposed first bottom layer and an exposed second bottom layer. The forming of the intermediate layer may include forming a first intermediate layer on the exposed first bottom layer and forming a second intermediate layer on the exposed second bottom layer, by plating copper on the exposed first bottom layer and the exposed second bottom layer.

The method may further include forming a first top layer on the first intermediate layer and forming a second top layer on the second intermediate layer, the first top layer and the second top layer including tin.

The forming of the first bottom layer and second bottom layer may include forming a preliminary bottom layer on an entirety of the semiconductor substrate, and patterning the preliminary bottom layer to form the first bottom layer on the first conductive semiconductor layer and the second bottom layer on the second conductive semiconductor layer before forming the resist pattern.

In the forming of the bottom layer, the bottom layer may be initially formed on an entirety of the semiconductor substrate. The forming of the resist pattern including the opening exposing the bottom layer may include forming the resist pattern to include a first opening exposing the bottom layer on the first conductive semiconductor layer and a second opening exposing the bottom layer on the second conductive semiconductor layer. After the removing of the resist pattern, the bottom layer may be patterned using the intermediate layer as a mask to provide a first bottom layer on the first conductive semiconductor layer and a second bottom layer on the second conductive semiconductor layer.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a solar cell according to an exemplary embodiment.

FIG. 2 to FIG. 7 sequentially illustrate cross-sectional views relating to stages of a method for manufacturing a solar cell shown in FIG. 1 according to an exemplary embodiment.

FIG. 8 illustrates a cross-sectional view of a solar cell according to another exemplary embodiment.

FIGS. 9 and 10 illustrate a cross-sectional views relating to stages of a method for manufacturing a solar cell according to another exemplary embodiment.

### DETAILED DESCRIPTION

Korean Patent Application No. 10-2011-0124527, filed on Nov. 25, 2011, in the Korean Intellectual Property Office, and entitled: “Solar Cell and Manufacturing Method Thereof,” is incorporated by reference herein in its entirety.

Example embodiments will now be described more fully hereinafter with reference to the accompanying drawings; however, they may be embodied in different forms and should not be construed as limited to the embodiments set forth herein.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

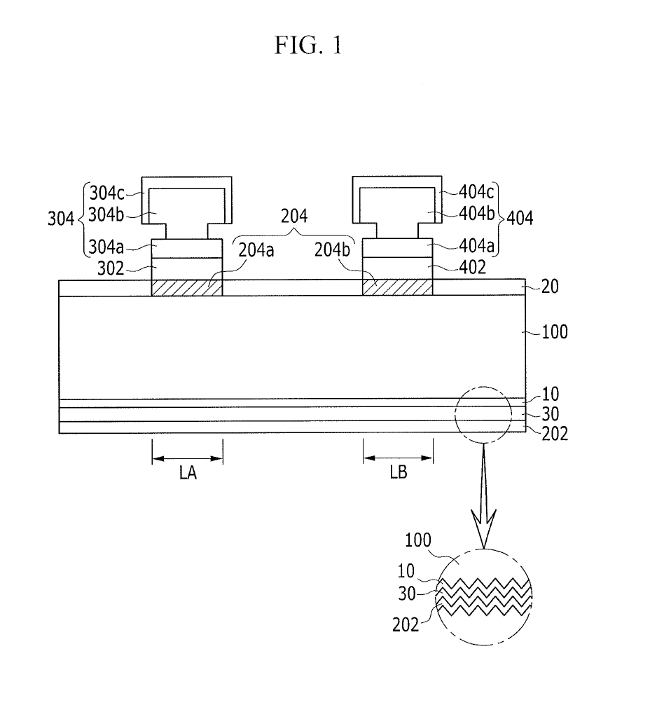

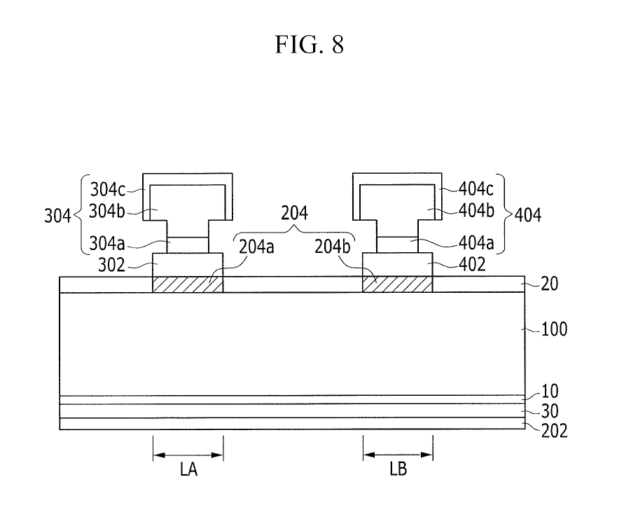

FIG. 1 shows a cross-sectional view of a solar cell according to a first exemplary embodiment, and FIG. 8 shows a cross-sectional view of a solar cell according to a second exemplary embodiment.

Referring to FIG. 1, the solar cell includes a semiconductor substrate 100. A surface on the semiconductor substrate 100 on which light is applied will be referred to herein as a front surface, and an opposite surface on which electrodes are formed will be referred to herein as a back surface.

The semiconductor substrate 100 may be a crystallized silicon (c-Si) wafer. The crystallization type may be one of a polycrystalline type, single crystalline type, and a microcrystalline type.

The semiconductor substrate 100 may be doped with a first conductive impurity. The first conductive impurity may be an n or a p type. The n-type impurity may be an impurity of a pentavalent element such as phosphorus (P), arsenic (As), or antimony (Sb). The p-type impurity may be an impurity of a trivalent element such as boron (B), gallium (Ga), or indium (In).

A doping layer 10 is formed on a front surface of the semiconductor substrate 100. The doping layer 10 may be formed over the entire front surface of the semiconductor substrate 100.

The doping layer 10 may be doped with the first conductive impurity in a like manner as the semiconductor substrate 100. The doping layer 10 may have a greater concentration of the first conductive impurity than the semiconductor substrate 100.

Regarding the doping layer 10, a potential barrier may be formed by a difference of impurity concentration between the semiconductor substrate 100 and the doping layer 10. A movement of holes to the front surface of the semiconductor substrate 100 may be hindered so that the first doping layer 10 may become a front surface field (FSF) of the solar cell for reducing a recombination of the electrons and the holes near the surface of the semiconductor substrate 100 and extinction thereof.

The front surface of the semiconductor substrate 100 may have protrusions and depressions. Reflectivity of the surface may be reduced and an amount of light that is absorbed may be increased because the light passing length in the solar cell is increased due to the protrusions and depressions on the surface. Therefore, a short circuit current of the solar cell may be improved.

A front surface protection film 30 may be formed on the semiconductor substrate 100.

The front surface protection film 30 may remove surface defects such as dangling bonds that may be provided on the surface of the semiconductor substrate 100, and thus may prevent the extinction of charges that move to the front surface of the semiconductor substrate 100.

The front surface protection film 30 may be configured with an i-type hydrogenated amorphous silicon film or i-type hydrogenated microcrystalline silicon film. The front surface protection film 30 may be formed to be about 0.5 nm to about 10 nm thick.

A front surface antireflection film 202 may be formed on the front surface protection film 30. The front surface antireflection film 202 may be formed on the entire semiconductor substrate 100 along the surface protrusions and depressions. The front surface antireflection film 202 may be formed to be a single layer or multiple layers made of silicon oxide or silicon nitride.

The front surface antireflection film 202 may allow more sunlight to be input due to a refractive index difference.

An intrinsic semiconductor layer 204 is formed on a back surface of the semiconductor substrate 100. The intrinsic semiconductor layer 204 may be formed with the same material as the front surface protection film 30.

A first conductive semiconductor layer 302 and a second conductive semiconductor layer 402 are provided on the intrinsic semiconductor layer. The first conductive semiconductor layer 302 and the second conductive semiconductor layer 402 are alternately disposed. The intrinsic semiconductor layer below the first conductive semiconductor layer 302 will be referred to herein as a first intrinsic semiconductor layer 204a, and the intrinsic semiconductor layer below the second conductive semiconductor layer 402 will be referred to herein as a second intrinsic semiconductor layer 204b.

When the doping layer 10 is n-type, the first conductive semiconductor layer 302 may include an n-type conductive impurity, such as phosphorus (P) or arsenic (As). In this instance, the first conductive impurity may be doped at a concentration of about 1×10¹⁸ to 1×10²¹ atoms/cm³. A p-type conductive impurity such as boron (B) may be doped to the second conductive semiconductor layer 402. The second conductive impurity may be doped at a concentration of about 1×10¹⁸ to 1×10²¹ atoms/cm³.

The first conductive semiconductor layer 302 and the second conductive semiconductor layer 402 may be formed to include hydrogenated amorphous silicon (a-Si:H) or hydrogenated microcrystalline silicon, and may be formed to be about 5 nm to about 50 nm thick.

A first electrode 304 and a second electrode 404 are formed on the first conductive semiconductor layer 302 and the second conductive semiconductor layer 402, respectively.

The first electrode 304 and the second electrode 404 may be configured as triple layers made up of bottom layers 304a and 404a, intermediate layers 304b and 404b, and top layers 304c and 404c, respectively.

The bottom layers 304a and 404a may be formed to include a transparent conductive oxide. For example, the bottom layers 304a and 404a may include at least one of fluorine-doped tin oxide (FTO), indium tin oxide (ITO), indium oxide (In₂O₃), indium tungsten oxide (IWO), indium titanium oxide (ITiO), indium molybdenum oxide (IMO), indium niobium oxide (INbO), indium gadolinium oxide (IGdO), indium zinc oxide (IZO), indium zirconium oxide (IZrO), aluminum-doped zinc oxide (AZO), zinc oxide (ZnO), boron-doped zinc oxide (BZO), and gallium-doped zinc oxide (GZO).

The intermediate layers 304b and 404b and the top layers 304c and 404c may be formed to include a material that can be plated. For example, the intermediate layers 304b and 404b may be formed to include a low-resistance material such as copper (Cu), and the top layers 304c and 404c may be formed to include tin (Sn).

When the bottom layers 304a and 404a are formed of a transparent conductive oxide, the transparent conductive oxide becomes a diffusion barrier. Accordingly, even if the electrode is formed to include a metal with low resistance and great diffusibility, such as copper, movement of such a metal to the p-type or n-type semiconductor layer below the bottom layers 304a and 404a may be prevented.

The bottom layers 304a and 404a may be formed with the transparent conductive oxide in the exemplary embodiment so that contact resistance with the semiconductor layer may be reduced compared to a case in which the electrode formed of aluminum. Therefore, an additional heat treatment process for reducing contact resistance need not be performed.

Also, in the exemplary embodiment, the p-type and n-type semiconductor layers may be formed and the electrode may be formed thereon so that the contact area is great. Therefore, a small contact area and reduced contact resistance that may result if the doping layer of the semiconductor substrate and the electrode were to be connected through a through hole may be avoided

As shown in FIG. 1, depending on the manufacturing method, the first electrode 304 and the second electrode 404 may be formed such that the intermediate layers 304b and 404b have a part that has a narrower width than the bottom layers 304a and 404a.

Further, as shown in FIG. 8, depending on the manufacturing method, the bottoms of the intermediate layers 304b and 404b may be formed to the same width as the bottom layers 304a and 404a, as will be described in detail together with the subsequent manufacturing method.

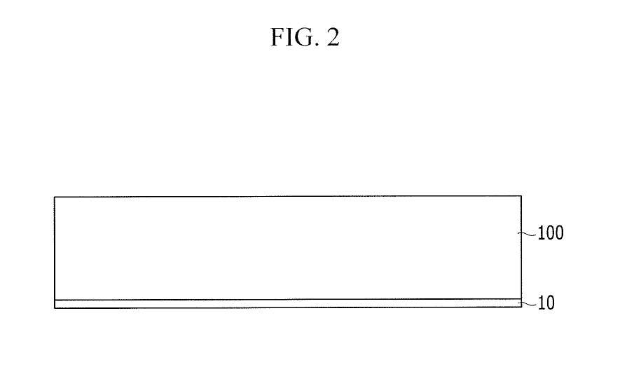

A method for manufacturing the solar cell will now be described with reference to FIGS. 2 to 10.

FIG. 2 to FIG. 7 are cross-sectional views sequentially showing stages of a method for manufacturing the solar cell shown in FIG. 1, according to an exemplary embodiment.

As shown in FIG. 2, a semiconductor surface 100 having a front surface and a back surface may be provided. Protrusions and depressions may be formed on the front surface the surface of the semiconductor substrate 100 by surface texturing.

The surface texturing method may include a chemical method for etching the surface using an etchant or an etching gas, and a method for forming grooves by using laser beams or forming pyramid shapes using a plurality of diamond edges.

A doping layer 10 may be formed by doping an n-type conductive impurity on the semiconductor substrate 100. The n-type conductive impurity may be phosphorus (P) or arsenic (As). The impurity may be inactivated inside the semiconductor substrate 100 through heat treatment.

When the n-type conductive impurity is doped, the surface and the impurity may react to form a phosphosilicate glass (PSG) film on the surface of the semiconductor substrate 100. The PSG film may include a metal impurity extracted from the inside of the semiconductor substrate 100 by diffusion. When diffusion is finished, diluted hydrofluoric acid (HF) may be used to eliminate the PSG film.

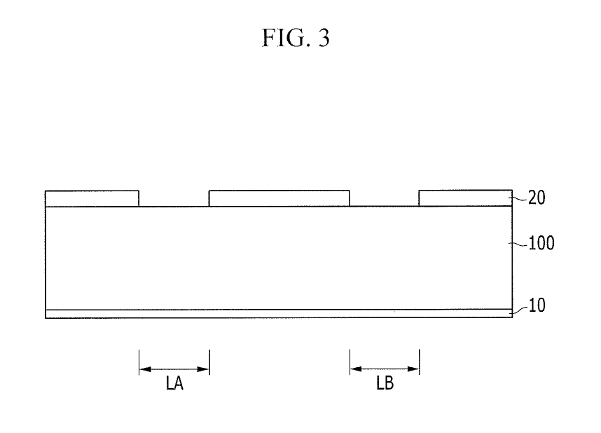

As shown in FIG. 3, an oxide layer 20 may be formed on the back surface of the semiconductor substrate 100. The oxide layer 20 may be formed by oxidizing the substrate or by depositing an oxide on the substrate.

The semiconductor substrate 100 may be exposed by removing the oxide layer 20 from the first area (LA) and the second area (LB) in which the first conductive semiconductor layer and the second conductive semiconductor layer are to be formed.

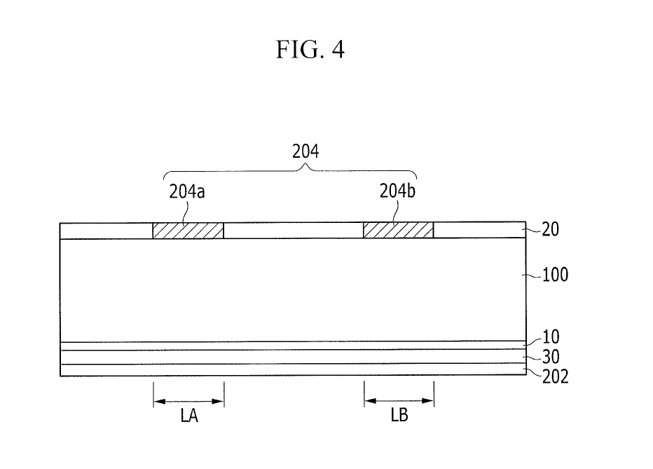

As shown in FIG. 4, a front surface protection film 30 and a back surface intrinsic semiconductor layer 204, including a first intrinsic semiconductor layer 204a and a second intrinsic semiconductor layer 204b, may be formed on the entire surface of the semiconductor substrate 100. The front surface protection film 30 and the back surface intrinsic semiconductor layer 204 may be formed simultaneously by providing an intrinsic amorphous silicon film to the front and back surfaces of the semiconductor substrate 100. The intrinsic amorphous silicon film that is formed on the back surface of the semiconductor substrate 100 may be patterned to leave the intrinsic amorphous silicon film in the first area (LA) and the second area (LB), thereby forming the intrinsic semiconductor layer 204 including the first intrinsic semiconductor layer 204a and the second intrinsic semiconductor layer 204b.

Silicon oxide or silicon nitride may be deposited on the front surface protection film 30 to form an antireflection film 202.

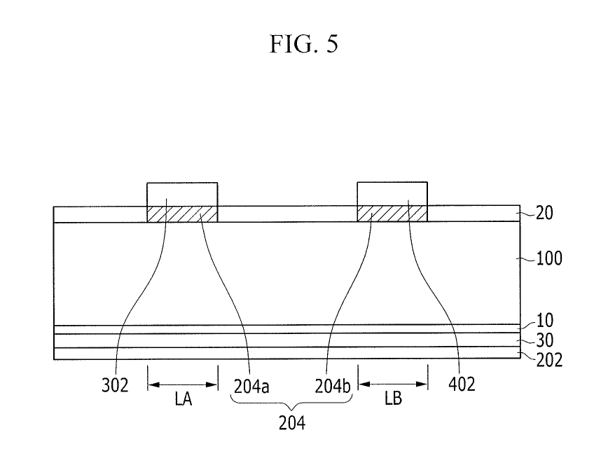

As shown in FIG. 5, a first conductive semiconductor layer 302 and a second conductive semiconductor layer 402 may be formed on the intrinsic semiconductor layer 204.

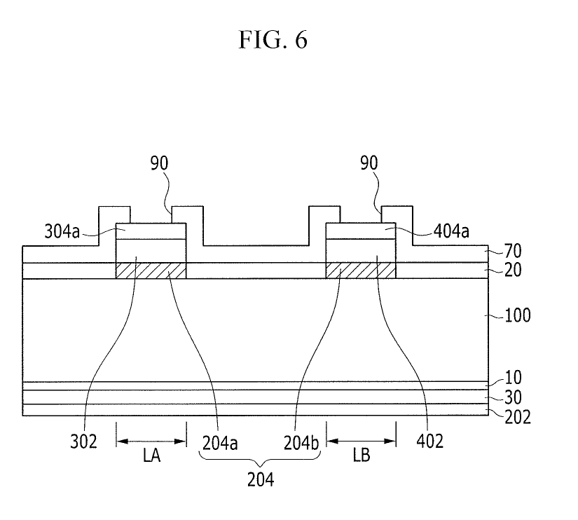

A transparent conductive oxide may be deposited and patterned on the first conductive semiconductor layer 302 and the second conductive semiconductor layer 402 to thus form the bottom layer 304a of the first electrode and the bottom layer 404a of the second electrode, as shown in FIG. 6.

A plating resist pattern 70 including an opening 90 that exposes a portion of the bottom layer 304a of the first electrode and a portion of the bottom layer 404a of the second electrode may be formed. The plating resist pattern 70 prevents the first conductive semiconductor layer 302, the second conductive semiconductor layer 402, and side walls of the bottom layers 304a and 404a from being exposed to the plating process.

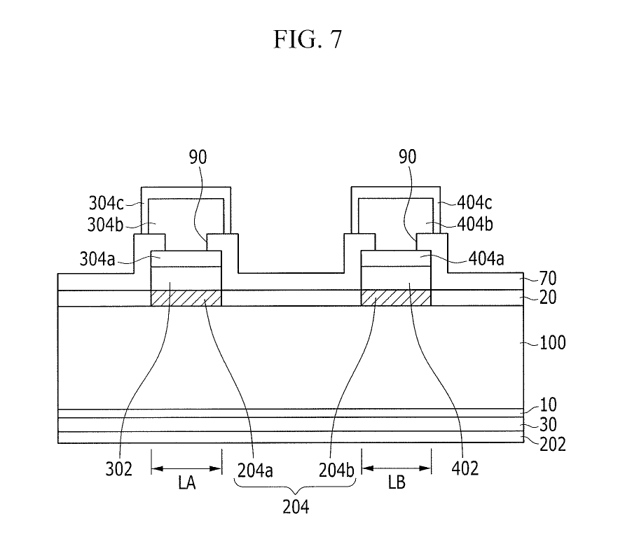

As shown in FIG. 7, intermediate layers 304b and 404b and top layers 304c and 404c may be formed on the bottom layer 304a and 404a through plating.

In the exemplary embodiment, the bottom layers are formed with the transparent conductive oxide and then are plated so that the bottom layers 304a and 404a become plating seed layers. Therefore, the formation of an additional seed layer for plating may be omitted.

As shown in FIG. 1, the plating resist pattern may be removed through cleansing to form a first electrode 304 and a second electrode 404 configured with the bottom layers 304a and 404a, the intermediate layers 304b and 404b, and the top layers 304c and 404c.

The process for removing the plating resist may be omitted depending on a characteristic of the plating resist. The plating resist may be removed if the plating resist is formed of a material such that the insulating property, chemical resistance, or thermal resistance of the plating resist is insufficient so is the plating resist may be changed by a high temperature while the solar cell module is manufactured or a bad effect may be given to solar cell module reliability. However, if the plating resist is a material with thermal resistance, chemical resistance, and high insulating property, such as a polyimide, the plating resist may be allowed to remain in the solar cell. In addition, the polyimide may include particles (e.g., TiO₂) that reflect sunlight. Accordingly, when such a polyimide is used for the plating resist, the plating resist may become a back surface reflecting film of the solar cell, and the removal process may be omitted.

Plating is not applied to the surface of the substrate where the plating resist pattern is formed. The intermediate layers 304b and 404b and the top layers 304c and 404c are formed by plating in the opening where the portion of the bottom layer is exposed. Accordingly, an additional photolithography process for etching the intermediate layers and the top layers is not needed. Therefore, the process for forming the electrode including the copper layer may be simplified.

For ease of understanding in FIG. 7, the intermediate layers 304b and 404b and the top layers 304c and 404c configured through plating are shown. The intermediate layers 304b and 404b and the top layers 304c and 404c may be formed in a mountain shape, and may grow laterally to have a same thickness as the bottom layer 304a and 404a so that the intermediate layers 304b and 404b and the top layers 304c and 404c may be provided on a portion of the plating resist pattern surrounding the opening that exposes a portion of the bottom layer 304a and 404a.

As shown in FIG. 6, the plating resist pattern 90 may be left on the side wall of the bottom layers 304b and 404b to thus protect the side walls so that a boundary of the plating resist pattern may be provided on the bottom layers 304a and 404a. Accordingly, the intermediate layers 304b and 404b may be formed to be narrower than the bottom layers 304a and 404a by the width of the opening of the plating resist pattern 90.

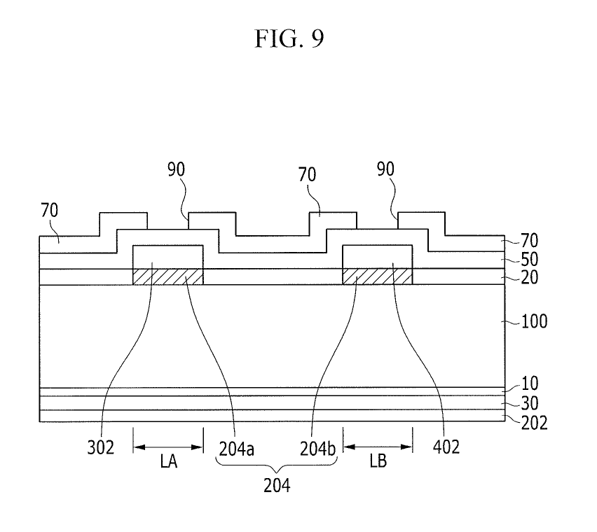

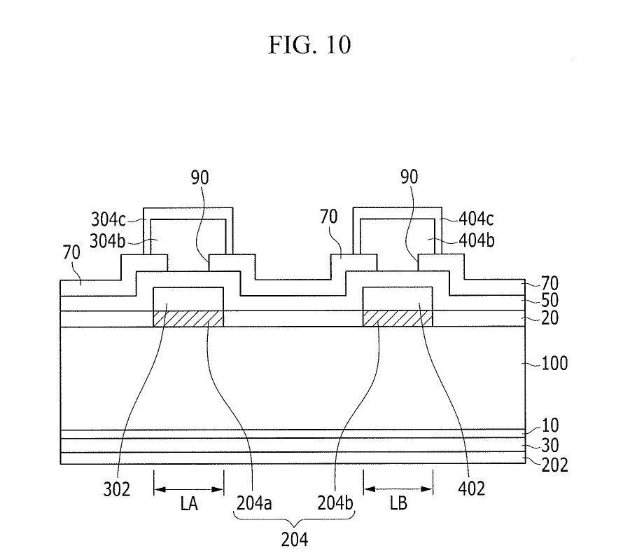

FIGS. 9 and 10 show cross-sectional views of a method for manufacturing a solar cell according to another exemplary embodiment. The method will now be described with reference to FIG. 2 to FIG. 5 and FIG. 8.

Protrusions and depressions may be formed on the front surface of the semiconductor substrate 100 shown in FIG. 2.

As shown in FIG. 3, a doping layer 10 is formed by doping an n-type conductive impurity on front surface of the semiconductor substrate 100.

As shown in FIG. 4, an oxide layer may be formed on a back surface of the semiconductor substrate 100. The oxide layer may be patterned to form an oxide layer 20 having an opening for exposing the first area (LA) and the second area (LB).

A protection film 30 and an intrinsic semiconductor layer 204 including a first intrinsic semiconductor layer 204a and a second intrinsic semiconductor layer 204b may be formed on the semiconductor substrate 100.

As shown in FIG. 5, a first conductive semiconductor layer 302 and a second conductive semiconductor layer 402 may be formed on the intrinsic semiconductor layers 204a and 204b.

As shown in FIG. 9, a transparent conductive layer 50 may be formed by depositing a transparent conductive oxide on the first conductive semiconductor layer 302 and the second conductive semiconductor layer 402.

A plating resist pattern 70 may be formed on the transparent conductive layer 50. The plating resist pattern 70 may include openings 90 for exposing the transparent conductive layer 50 in locations corresponding to the first conductive semiconductor layer 302 and the second conductive semiconductor layer 402.

As shown in FIG. 10, intermediate layers 304b and 404b made of copper and top layers 304c and 404c made of tin may be formed on the transparent conductive layer 50 through plating. In the exemplary embodiment, the transparent conductive layer 50 may be formed and a plating process may then be performed so that the transparent conductive layer becomes a plating seed layer. Therefore, the formation of an additional seed layer may be omitted.

The intermediate layers 304b and 404b and the top layers 304c and 404c may be formed on the conductive layers in the first area (LA) and the second area (LB) where the electrode is formed so a photolithography process for patterning the intermediate layers 304b and 404b and the top layers 304c and 404c is not needed. Hence, the process for forming a copper electrode is simplified.

The plating resist pattern 70 may be removed through cleansing or wet etching, and the bottom layers 304a and 404a may be formed by etching the transparent conductive layer 50 using the intermediate layers 304b and 404b and the top layers 304c and 404c as masks. Therefore, as shown in FIG. 8, the first electrode 304 and the second electrode 404 configured with the bottom layers 304a and 404a, the intermediate layers 304b and 404b, and the top layers 304c and 404c.

The transparent conductive layer may be wet etched with the intermediate layers 304b and 404b and the top layers 304c and 404c as masks so that an undercut may be formed below the intermediate layers 304b and 404b and the top layers 304c and 404c. The bottom widths of the intermediate layers 304b and 404b and the width of the bottom layers 304a and 404a may be formed to be narrower than that of the top layer.

By way of summation and review, a typical electrode used as a plated electrode of a solar cell may include a seed layer including a copper thin film for plating, a diffusion barrier layer (e.g., TiW) at the bottom of the seed layer for preventing the copper from being diffused into a crystalline silicon substrate, and a metal layer (e.g., Al, Ag) for providing an ohmic contact with the crystalline silicon at the bottom of the diffusion barrier layer. However, triple layers including an aluminum layer, a titanium tungsten (TiW) layer, and a seed layer typically must be deposited by using a sputtering process under a high vacuum state, increasing the cost and process time. Also, an aluminum layer, titanium tungsten layer, and seed layer may respectively require an etching process for division into p-type and n-type electrodes after the layers are formed.

Embodiments disclosed herein advance the art by providing a solar cell for which a simplified manufacturing process may be used while forming an electrode including copper, and a manufacturing method thereof A copper layer may be selectively formed in specific parts where p-type and n-type electrodes are positioned, so that the process for etching the copper layer may be reduced and the manufacturing process may be simplified.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a semiconductor substrate;
a first intrinsic semiconductor layer and a second intrinsic semiconductor layer on the semiconductor substrate, the first intrinsic semiconductor layer and the second intrinsic semiconductor layer being spaced apart from each other;
a first conductive semiconductor layer and a second conductive semiconductor layer respectively disposed on the first intrinsic semiconductor layer and the second intrinsic semiconductor layer; and
a first electrode and a second electrode, including a bottom layer on the first conductive semiconductor layer and the second conductive semiconductor layer, respectively, the bottom layer including a transparent conductive oxide, and an intermediate layer on the bottom layer, the intermediate layer including copper.

2. The solar cell as claimed in claim 1, wherein
the intermediate layer includes a part that is narrower than the bottom layer.

3. The solar cell as claimed in claim 1, wherein
the intermediate layer includes a part having a width that is equivalent to a width of the bottom layer.

4. The solar cell as claimed in claim 1, further including a top layer on the intermediate layer, the top layer including tin.

5. The solar cell as claimed in claim 4, wherein the top layer covers the intermediate layer.

6. The solar cell as claimed in claim 1, wherein
the transparent conductive oxide includes at least one of fluorine-doped tin oxide, indium tin oxide, indium oxide, indium tungsten oxide, indium titanium oxide, indium molybdenum oxide, indium niobium oxide, indium gadolinium oxide, indium zinc oxide, indium zirconium oxide, aluminum-doped zinc oxide, zinc oxide, boron-doped zinc oxide, and gallium-doped zinc oxide.

7. The solar cell as claimed in claim 1, wherein:
the first conductive semiconductor layer is doped with a p-type conductive impurity, and
the second conductive semiconductor layer is doped with an n-type conductive impurity.

8. The solar cell as claimed in claim 7, wherein the semiconductor substrate is in a form of a crystalline semiconductor.

9. The solar cell as claimed in claim 8, wherein the first conductive semiconductor layer, the second conductive semiconductor layer, the first intrinsic semiconductor layer, and the second intrinsic semiconductor layer include amorphous silicon.

10. A method for manufacturing a solar cell, the method comprising:
forming a first intrinsic semiconductor layer and a second intrinsic semiconductor layer on a semiconductor substrate;
forming a first conductive semiconductor layer and a second conductive semiconductor layer on the first intrinsic semiconductor layer and the second intrinsic semiconductor layer, respectively;
forming a bottom layer including a transparent conductive oxide on the first conductive semiconductor layer and the second conductive semiconductor layer;
forming a resist pattern on the semiconductor substrate, the resist pattern including an opening exposing the bottom layer to provide an exposed bottom layer;
forming an intermediate layer by plating copper on the exposed bottom layer; and
removing the resist pattern.

11. The method as claimed in claim 10, further including
forming a top layer with tin on the intermediate layer.

12. The method as claimed in claim 10, wherein the forming of the bottom layer includes removing the bottom layer between the first conductive semiconductor layer and the second conductive semiconductor layer.

13. The method as claimed in claim 10, wherein in the forming of the bottom layer, the bottom layer is formed on an entirety of the semiconductor substrate.

14. The method as claimed in claim 13, wherein, after the removing of the resist pattern, the bottom layer between the first conductive semiconductor layer and the second conductive semiconductor layer is removed using the intermediate layer as a mask.

15. The method as claimed in claim 10, wherein:
the forming of the bottom layer includes forming a first bottom layer on the first conductive semiconductor layer and forming a second bottom layer on the second conductive semiconductor layer, the first bottom layer and the second bottom layer each including the transparent conductive oxide;
the forming of the resist pattern includes forming the resist pattern to include openings exposing the first bottom layer on the first conductive semiconductor layer and the second bottom layer on the second conductive semiconductor layer to provide an exposed first bottom layer and an exposed second bottom layer; and
the forming of the intermediate layer includes forming a first intermediate layer on the exposed first bottom layer and forming a second intermediate layer on the exposed second bottom layer, by plating copper on the exposed first bottom layer and the exposed second bottom layer.

16. The method as claimed in claim 15, further including forming a first top layer on the first intermediate layer and forming a second top layer on the second intermediate layer, the first top layer and the second top layer including tin.

17. The method as claimed in claim 15, wherein the forming of the first bottom layer and second bottom layer includes:
forming a preliminary bottom layer on an entirety of the semiconductor substrate, and
patterning the preliminary bottom layer to form the first bottom layer on the first conductive semiconductor layer and the second bottom layer on the second conductive semiconductor layer before forming the resist pattern.

18. The method as claimed in claim 10, wherein:
in the forming of the bottom layer, the bottom layer is initially formed on an entirety of the semiconductor substrate,
the forming of the resist pattern including the opening exposing the bottom layer includes forming the resist pattern to include a first opening exposing the bottom layer on the first conductive semiconductor layer and a second opening exposing the bottom layer on the second conductive semiconductor layer; and
after the removing of the resist pattern, the bottom layer is patterned using the intermediate layer as a mask to provide a first bottom layer on the first conductive semiconductor layer and a second bottom layer on the second conductive semiconductor layer.
